(19) United States
(12) Patent Application Publication
(10) Pub. No.: US 2008/0002840 A1
(43) Pub. Date: Jan. 3, 2008

(54) Radio with automatic voice enhancement

(76) Inventor: Barry Wallenstein, Colts Neck, NJ (US)

Correspondence Address: LAW OFFICE OF BRETT N. DORNY, 386 WEST MAIN STREET, SUITE 12A, NORTHBOROUGH, MA, 01532, US

(21) Appl. No.: 11/479,650

(22) Filed: Jun. 30, 2006

(51) Int. Cl. H03G 3/00

(52) U.S. Cl. 381/107

(57) ABSTRACT

A voice enhancement circuit is used in a conventional VHF radio to control volume when transmissions are received from multiple sources on a single frequency. The voice enhancement circuit includes an audio analyzer for determining a loudness level of the signal from the conventional VHF radio. A controllable amplifier receives an output from the audio analyzer. The controllable amplifier buffers or amplifies the audio output, based upon the output from the audio analyzer in order to provide a constant output level to the radio speaker.

### BACKGROUND OF THE INVENTION

1. Field of the Invention

The present invention relates to two-way VHF radios. More particularly, it relates to two-way VHF radios including automatic volume control.

2. Discussion of Related Art

All commercial shipping vessels are required, by policy or regulation, to simultaneously monitor various VHF frequencies. Often, these requirements result in use of at least three or four different radios, each at a different frequency. An example radio setup could include:

1. One or two for Port Operations;

2. One for Bridge-to-Bridge communications;

3. One for monitoring progress of the deck or engine room crew; and

4. One for internal Company communications.

When trying to listen to and comprehend transmissions from multiple radios simultaneously, it is extremely difficult to hear and understand every transmission. This difficulty is complicated by the standard operation of volume control for commercially available radios. The operator typically uses a knob to select a volume level for each radio. The operator will try to balance the volumes on each radio to his or her desired listening level. However, since multiple transmissions can be received on a single frequency from different sources, the volume control is inadequate.

With current radios, the audio output of each radio is transmitted at a different volume level for each received communication. The volume of the audio output depends not only on the amplification and the speaker volume, but also upon the characteristics of the person sending the transmission. Since the characteristics of the sender contribute to the output volume, the operator at the receiver has insufficient control.

If someone transmitting a message from another location on a designated frequency is holding the microphone 12 inches from their mouth while speaking softly, anyone receiving the message would have a difficult time hearing and understanding the weak message. On the other hand, if someone else is transmitting on the same frequency while holding the microphone to their mouth and almost shouting into it, the received message would be loud and unbearable. The operator, therefore, would be forced to reduce the volume of the radio while receiving transmissions from the loud party. However, subsequent messages from the softly spoken party could be lost to the radio operator due to the reduced volume of the radio. The operator would be required to constantly adjust the volume. Furthermore, since transmissions from any party could occur at any time, the operator cannot anticipate party speaking and adjust the volume before the transmission.

Having to constantly change the volume level of each radio is more than just a nuisance. Constant attention to this matter creates a major distraction that reduces “Situational Awareness” and promotes an unsafe operating condition. Maintaining a high level of “Situational Awareness” at all times is crucial to operating safely, and part of that obligation dictates that the operator must hear and understand everything that is happening all around, all of the time. Therefore, a need exists for a radio which avoids overly loud and overly soft transmissions, one which eliminates the need for the operator to constantly adjust radio volume.

The problems with volume control are not entirely unique to radios for shipping vessels. All audio systems must account for differences in input signal strength and variation in output volume. A number of automatic gain control devices have been devised for inclusion in audio systems to correct for variations in signal strength. For example, some systems measure the level of ambient noise and automatically adjust the volume to account for the noise conditions. Other systems adjust the volume based upon the input devices to provide a constant volume. Thus, as the user changes the input to the audio system from a CD player to radio, or from one channel on the TV or radio to another, the volume does not change wildly. Other systems measure the output volume and transmit a signal back to the source to control operation of the source, i.e., the microphone, to account for variations in signal levels. Other systems constantly adjust input levels to maintain them within a desired range.

However, existing automatic gain control systems cannot be used to resolve the problems for commercial shipping radio operators. The difficulty arises from multiple transmissions over a single frequency. The receiving radio cannot adjust for changed inputs because it does not control the inputs. Furthermore, it cannot utilize operations which automatically adjust input levels to a desired range since most of the time no transmission is received. Such a system would amplify noise during the times of non-transmission. Therefore, a need remains for a system which automatically assists a radio operator in achieving desirable volume levels from disparate transmission levels.

### SUMMARY OF THE INVENTION

The present invention provides a voice enhancement feature which automatically adjusts the volume at the speaker to account for different transmissions sources. The voice enhancement feature comprises a circuit between the antenna, frequency selection, and reception circuitry of a standard radio and the speaker. After a signal is received and processed to become an audio output to the speaker, the audio output is analyzed by the voice enhancement circuit to determine its signal strength. This signal is then amplified or muted within the voice enhancement circuit, to a desired level. The voice enhancement circuit includes a minimum level for the audio output in order to provide enhancement. In this manner, noise is not amplified during non-transmission times.

### BRIEF DESCRIPTION OF THE DRAWINGS

FIG. 1 is a block diagram of radio circuitry including a voice enhancement circuit according to an embodiment of the invention.

### DETAILED DESCRIPTION

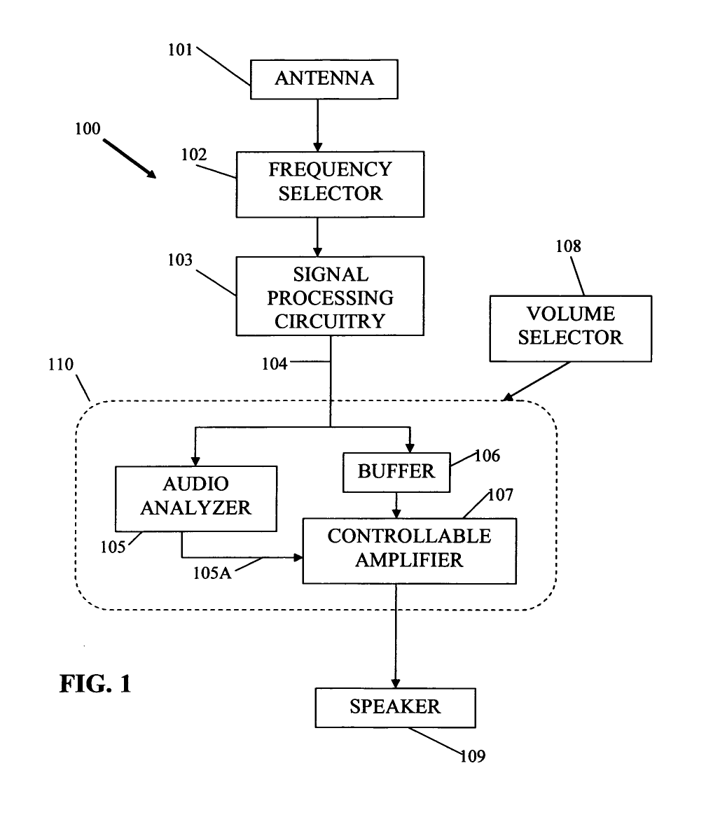

A radio having a voice enhancement circuit according to the present invention is illustrated in FIG. 1. As shown in FIG. 1, a VHF radio 100 consists of primary circuitry for receiving and processing transmission signals on different frequencies. The VHF radio 100 includes an antenna 101, frequency selector 102, and signal processing circuitry 103. These are standard components of a radio for receiving and processing transmission signals. The frequency selector 102 operates to select the desired frequency to be received on the radio. The signal processing circuitry 103 encompasses normal volume and squelch controls and other known controls and circuitry. In a standard radio, the audio output 104 from the signal processing circuitry 103 would be inputted directly to the speaker 109 to produce the audio sound for the operator.

The present invention includes a voice enhancement circuit 110 for processing the audio output 104 before being supplied to the speaker 109. The voice enhancement circuit 110 includes an audio analyzer 105, a buffer 106, and a controllable amplifier 107. The audio output 104 is fed to both the audio analyzer 105 and the buffer 106. The audio analyzer 105 evaluates the audio output 104 to determine its signal level. The audio analyzer 105 outputs a control signal 105A to the controllable amplifier 107. The controllable amplifier operates on the audio output 104 to adjust the volume level based upon the control signal 105A. Depending upon the actual components used in the voice enhancement circuit 110, the control signal 105A may be the determined signal level or may be an adjustment amount to be applied to the audio output 104. The buffer 106 operates to delay the audio output 104 to the controllable amplifier. The delay in the buffer 106 is sufficient to allow the audio analyzer 105 to complete the evaluation of the audio output 104 and to provide the control signal 105A. Thus, the controllable amplifier 107 is set by the control signal 105A corresponding the audio output 104 coming from the buffer 106 to avoid any portions of the transmission which are too loud or too soft.

A volume selector 108 constitutes an input to the voice enhancement circuit 110. Depending upon the circuitry used for the voice enhancement circuit 110, the volume selector 108 may be connected to the audio analyzer 105 or the controllable amplifier 107 to provide the desired volume for the speaker 109. The controllable amplifier 107 either buffers or amplifies the audio output 104 to the desired level as determined by the control signal 105A and, possibly, the volume selector 108. The output of the controllable amplifier 107 is provided to the speaker 109.

The volume selector 108 is used by the operator to set a desirable volume. It may be an analog or digital input. It may be a relative level or a specific loudness level. Either way, within the voice enhancement circuit 110, the desired volume corresponds to a signal level. For example, the volume could be set at a normal listening level of 60 decibels. When a transmission is received from the soft spoken party, the audio output 104 may only be at 30 decibels. The audio analyzer 105 determines the level and provides the control signal 105A to the controllable amplifier 107. The controllable amplifier 107, based upon the control signal, enhances or amplifies the audio signal 104 so that it reaches the speaker 109 with an intended output of 60 decibels. Thus, the transmission is heard comfortably without further adjustment of the volume of the radio.

When a transmission is received from the person nearly shouting into the microphone, the audio output may be at 90 decibels (or even more). Again, the audio analyzer 105 determines the level and provides the control signal 105A to the controllable amplifier. In this case, the controllable amplifier 107 mutes or reduces the audio output 104 to the desired listening level of 60 decibels before providing the signal to the speaker 109. All transmissions, no matter how they would normally be received, would be sent to the speaker at the same volume level.

Additionally, the audio analyzer 105 may include a minimum signal level. If the audio output 104 does not meet that minimum level, the control signal 105A is not used to adjust the audio output 104. With this operation, noise is not inadvertently amplified to normal listening levels. Depending upon the specific circuitry used in the signal processing circuitry 103, a minimum level may not be needed. The signal processing circuitry 103 may not provide an audio output 104 when no transmission is being received.

Having disclosed at least one embodiment of the present invention, various adaptations, modifications, additions, and improvements will be readily apparent to those of ordinary skill in the art. Such adaptations, modifications, additions and improvements are considered part of the invention which is only limited by the several claims attached hereto.

1. An apparatus for controlling the volume of a two-way radio receiver comprising:
an input for receiving a processed output of the radio receiver when a transmission is received;
a buffer coupled to the input for delaying the processed output;
an analyzer coupled to the input to receive the processed output and determine a signal level of the processed output;
a controllable amplifier coupled to the buffer to receive the delayed processed output and coupled to the analyzer to adjust an output signal level for the delayed processed output based upon the determined signal level; and
an output providing the adjusted processed output.

2. The apparatus for controlling volume of a two-way radio receiver according to claim 1, further comprising a volume selector for setting a desired volume level.

3. The apparatus for controlling volume of a two-way radio receiver according to claim 2, wherein the volume selector is coupled to the analyzer and wherein the analyzer includes an output to the controllable amplifier representative of an adjustment to the output signal level.

4. The apparatus for controlling volume of a two-way radio receiver according to claim 2, wherein the volume selector is coupled to the controllable amplifier and wherein the analyzer includes an output to the controllable amplifier representative of the determined signal level.

5. The apparatus for controlling volume of a two-way radio receiver according to claim 1, wherein the controllable amplifier does not increase the signal level if the determined signal level is below a predetermined level.

6. The apparatus for controlling volume of a two-way radio receiver according to claim 1, wherein the output is provided to a speaker of the radio.

7. A method for controlling volume of a two-way radio receiver comprising the steps of:
delaying a processed output of the radio receiver;
determining a signal level of the processed output; and
adjusting the signal level of the delayed processed output based upon the determined signal level.

8. The method for controlling volume of a two-way radio receiver according to claim 7, further comprising the step of providing the delayed processed output to a speaker after the adjusting step.

9. The method for controlling volume of a two-way radio receiver according to claim 7, further comprising the step of receiving an input indicative of a desired volume; and
wherein the adjusting step adjusts the signal level of the delayed processed output based upon a difference between the desired volume and the determined signal level.

10. The method for controlling volume of a two-way radio receiver according to claim 7, further comprising the step of determining when the signal level of the processed output is below a predetermined level; and
wherein the adjusting step is not performed if the processed output is below the predetermined level.

11. A two-way radio receiver comprising:
a signal processor for processing incoming transmissions and providing a processed output;
a buffer coupled to the signal processor for delaying the processed output;
an analyzer coupled to the signal processor to receive the processed output and determine a signal level of the processed output;
a controllable amplifier coupled to the buffer to receive the delayed processed output and coupled to the analyzer to adjust an output signal level for the delayed processed output based upon the determined signal level; and
a speaker coupled to the controllable amplifier to produce an output from the delayed processed output.

12. The two-way radio receiver according to claim 11, further comprising a volume selector for setting a desired volume level.

13. The two-way radio receiver according to claim 12, wherein the volume selector is coupled to the analyzer and wherein the analyzer includes an output to the controllable amplifier representative of an adjustment to the output signal level.

14. The two-way radio receiver according to claim 12, wherein the volume selector is coupled to the controllable amplifier and wherein the analyzer includes an output to the controllable amplifier representative of the determined signal level.
